(19) United States
(12) Patent Application Publication
(10) Pub. No.: US 2017/0110471 A1
(43) Pub. Date: Apr. 20, 2017

(54) SEMICONDUCTOR DEVICE AND METHOD FOR MANUFACTURING SAME

(71) Applicant: Kabushiki Kaisha Toshiba, Minato-ku (JP)

(72) Inventors: Yasuhito YOSHIMIZU, Yokkaichi (JP); Masaki TSUJI, Yokkaichi (JP); Akifumi GAWASE, Kuwana (JP)

(73) Assignee: Kabushiki Kaisha Toshiba, Minato-ku (JP)

(21) Appl. No.: 15/046,643

(22) Filed: Feb. 18, 2016

Related U.S. Application Data
(60) Provisional application No. 62/242,572, filed on Oct. 16, 2015.

(51) Int. Cl. H01L 27/115; H01L 29/417; H01L 29/40

(52) U.S. Cl. CPC H01L 27/11582; H01L 27/11556; H01L 29/401; H01L 29/41741

(57) ABSTRACT

According to one embodiment, the stacked body includes a plurality of electrode layers stacked with an insulator interposed. The semiconductor body extends in a stacking direction through the stacked body. The semiconductor body includes an upper end portion protruding above the stacked body. The stacked film is provided between the semiconductor body and the electrode layers. The stacked film includes a charge storage portion. The conductor is provided at an upper surface and a side surface of the upper end portion of the semiconductor body. The conductor electrically contacts the upper surface and the side surface. The interconnect is provided above the conductor. The interconnect is electrically connected to the conductor.

### CROSS-REFERENCE TO RELATED APPLICATION

This application is based upon and claims the benefit of priority from U.S. Provisional Patent Application 62/242,572, filed on Oct. 16, 2015; the entire contents of which are incorporated herein by reference.

### FIELD

Embodiments described herein relate generally to a semiconductor device and a method for manufacturing the same.

### BACKGROUND

A three-dimensional memory device has been proposed to have a structure in which a semiconductor body extends in a pipe-like configuration or a columnar configuration above a substrate and pierces a stacked body including a plurality of electrode layers, and the upper surface of the semiconductor body is electrically connected to a bit line. In such a device, the electrical contact surface area between the semiconductor body and the bit line becomes small as thinner films or smaller diameters progress for the semiconductor body. This may cause an increase of the contact resistance between the semiconductor body and the bit line.

### BRIEF DESCRIPTION OF THE DRAWINGS

FIG. 1 is a schematic cross-sectional view of a semiconductor device of an embodiment;

FIGS. 2A and 2B are schematic plan views showing planar layout of a part of components of the semiconductor device of the embodiment;

FIG. 3A is a cross-sectional view of a memory cell of the embodiment;

FIG. 3B is an A-A′ cross-sectional view of FIG. 3A;

FIG. 4A is a cross-sectional view of a memory cell of the embodiment;

FIG. 4B is an B-B′ cross-sectional view of FIG. 4A;

FIG. 5A is a schematic top view of a semiconductor body and a conductor of the embodiment;

FIG. 5B is a C-C′ cross-sectional view of FIG. 5A;

FIGS. 6A to 17B are schematic cross-sectional views showing a method for manufacturing the semiconductor device of the embodiment;

FIG. 18 is a schematic cross-sectional view of a semiconductor device of another embodiment; and

FIG. 19 is a schematic cross-sectional view of a semiconductor device of another embodiment.

### DETAILED DESCRIPTION

According to one embodiment, a semiconductor device includes a substrate, a stacked body, a semiconductor body, a stacked film, a conductor, and an interconnect. The stacked body is provided above the substrate. The stacked body includes a plurality of electrode layers stacked with an insulator interposed. The semiconductor body extends in a stacking direction through the stacked body. The semiconductor body includes an upper end portion protruding above the stacked body. The stacked film is provided between the semiconductor body and the electrode layers. The stacked film includes a charge storage portion. The conductor is provided at an upper surface and a side surface of the upper end portion of the semiconductor body. The conductor electrically contacts the upper surface and the side surface. The interconnect is provided above the conductor. The interconnect is electrically connected to the conductor.

Embodiments will now be described with reference to the drawings. The same components are marked with the same reference numerals in the drawings.

A semiconductor device of an embodiment is a semiconductor memory device including a memory cell array having a three-dimensional structure.

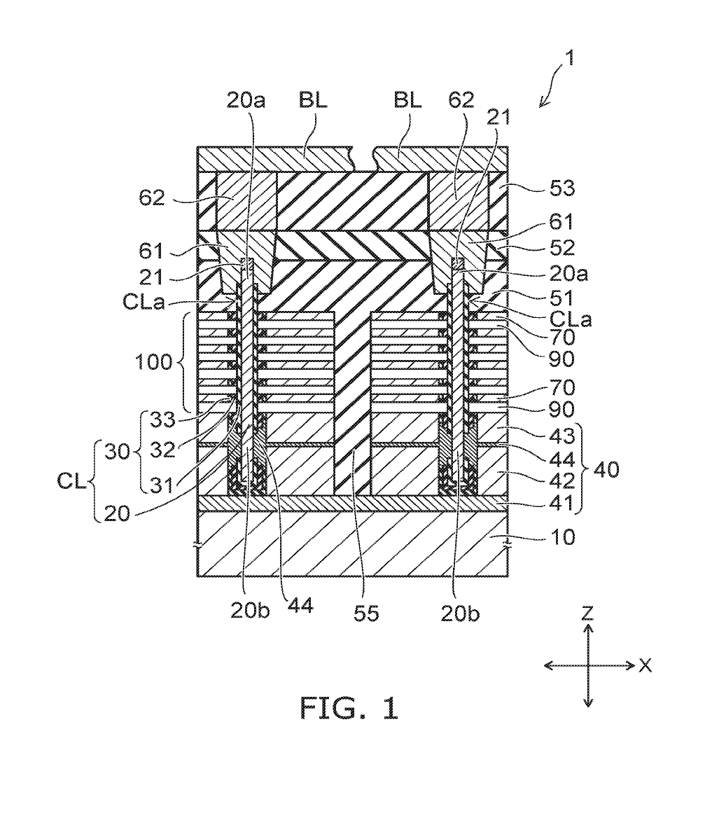

FIG. 1 is a schematic cross-sectional view of the memory cell array 1 of the embodiment.

The memory cell array 1 includes a substrate 10, a source layer 40 provided on the substrate 10 as a conductive layer, a stacked body 100 provided on the source layer 40, a plurality of columnar units CL, and a plurality of bit lines BL provided above the stacked body 100 as interconnects.

The stacked body 100 includes a plurality of electrode layers 70 stacked with air gaps 90 interposed as an insulator. The plurality of electrode layers 70 are stacked at a prescribed period with the air gaps 90 interposed in a direction (a Z-direction) perpendicular to a major surface of the substrate 10. The electrode layers 70 are, for example, tungsten layers or molybdenum layers.

The air gap 90 is made between the electrode layers 70 adjacent to each other above and below in the stacking direction (the Z-direction). An insulating film may be provided instead of the air gap 90 as the insulator.

The source layer 40 is provided between the substrate 10 and the stacked body 100. The source layer 40 includes a first conductive layer 41, a second conductive layer 42, a third conductive layer 43, and an intermediate conductive film 44. The first conductive layer 41 is provided on the substrate 10; the second conductive layer 42 is provided on the first conductive layer 41; the intermediate conductive film 44 is provided on the second conductive layer 42; and the third conductive layer 43 is provided on the intermediate conductive film 44.

The first conductive layer 41 is a metal layer and is, for example, a tungsten layer or a molybdenum layer. The second conductive layer 42 and the third conductive layer 43 are, for example, polycrystalline silicon layers doped with an impurity. The intermediate conductive film 44 is, for example, a polycrystalline silicon film doped with an impurity.

The electrode layer 70 of the lowermost layer is provided, with the air gap 90 interposed, on the third conductive layer 43. An insulating layer 51 is provided on the electrode layer 70 of the uppermost layer; an insulating layer 52 is provided on the insulating layer 51; and an insulating layer 53 is provided on the insulating layer 52.

The stacked body 100 is divided in an X-direction parallel to the major surface of the substrate 10 by an insulating separation unit 55. The insulating separation unit 55 pierces the stacked body 100, the third conductive layer 43, the intermediate conductive film 44, and the second conductive layer 42, extends in the Z-direction, and reaches the first conductive layer 41.

The bit lines BL are provided on the insulating layer 53. The columnar unit CL is formed in a circular columnar or elliptical columnar configuration extending in the Z-direction through the stacked body 100. Also, the columnar unit CL includes an upper end portion CLa protruding above the stacked body 100. The upper end portion CLa of the columnar unit CL includes an upper end portion 20a of a semiconductor body 20 described below. The upper end portion 20a of the semiconductor body 20 is connected to the bit line BL via a conductor 61 and a connector 62.

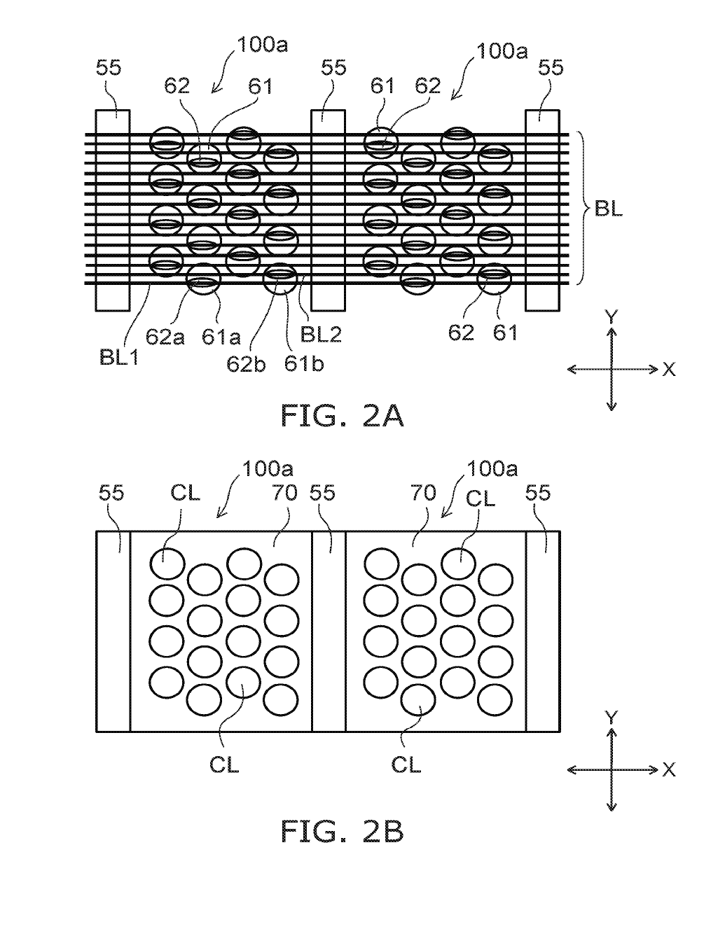

FIG. 2A is a schematic plan view showing a planar layout of the conductors 61, the connectors 62, the bit lines BL, and the insulating separation units 55.

FIG. 2B is a schematic plan view showing a planar layout of the electrode layers 70, the columnar units CL, and the insulating separation units 55.

In FIG. 2A and FIG. 2B, a Y-direction is a direction parallel to the major surface of the substrate 10 and orthogonal to the X-direction. The page surface depth direction in FIG. 1 corresponds to the Y-direction.

The insulating separation unit 55 extends in the Y-direction and divides the stacked body 100 into a plurality of blocks 100a in the X-direction. The plurality of columnar units CL are arranged in each block 100a as shown in FIG. 2B. For example, the plurality of columnar units CL have a staggered arrangement. Or, the plurality of columnar units CL may have a square lattice arrangement along the X-direction and the Y-direction.

The plurality of conductors 61 and the plurality of connectors 62 are arranged to correspond to the number and arrangement of the plurality of columnar units CL.

As shown in FIG. 2A, the plurality of bit lines BL extend in the X-direction to cross above the connectors 62. The plurality of bit lines BL are separated from each other in the Y-direction.

The plurality of columnar units CL, each of which is selected from each of blocks 100a, are connected to one common bit line BL via the conductor 61 and the connector 62. The connection portion between the columnar unit CL and the bit line BL is described below in detail.

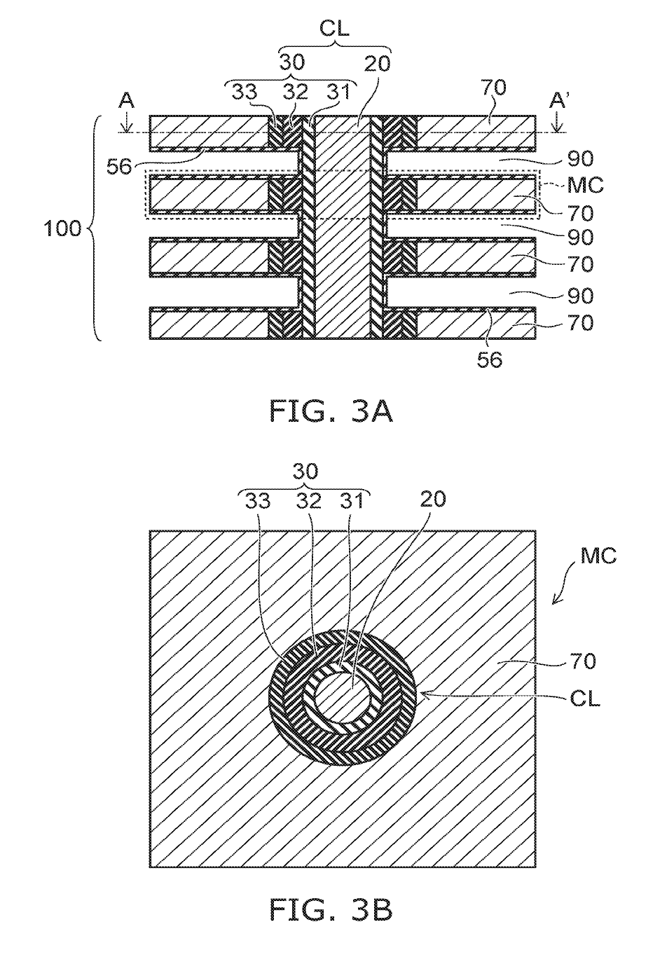

FIG. 3A is an enlarged cross-sectional view of one portion of the stacked body 100 and one portion of the columnar units CL shown in FIG. 1; and FIG. 3B is an A-A′ cross-sectional view of FIG. 3A.

The columnar unit CL includes the semiconductor body 20, and a memory film 30 which is a stacked film including a charge storage portion.

Specifically, the memory film 30 is a stacked film that includes a tunneling insulating film 31, a charge storage film 32, and a blocking insulating film 33. The blocking insulating film 33, the charge storage film 32, and the tunneling insulating film 31 are provided between the semiconductor body 20 and the electrode layers 70 in order from the electrode layer 70 side. The tunneling insulating film 31 contacts the semiconductor body 20. The blocking insulating film 33 contacts the electrode layers 70. The charge storage film 32 is provided between the blocking insulating film 33 and the tunneling insulating film 31.

The semiconductor body 20 has a columnar configuration and extends in the stacking direction through the stacked body 100. The tunneling insulating film 31 is provided in a pipe-like configuration surrounding the semiconductor body 20 from the outer circumferential side. The semiconductor body 20 and the tunneling insulating film 31 are continuous in the stacking direction of the stacked body 100.

The blocking insulating film 33 and the charge storage film 32 are divided in the stacking direction with the air gaps 90 interposed. The memory film 30 is not interposed between the electrode layers 70 above and below. The air gap 90 between the electrode layers 70 above and below extends to the tunneling insulating film 31 side to divide the blocking insulating film 33 and the charge storage film 32 in the stacking direction.

The charge storage film 32 is provided between the blocking insulating film 33 and the tunneling insulating film 31, and surrounds the tunneling insulating film 31 from the outer circumferential side.

The blocking insulating film 33 is provided between the charge storage film 32 and the electrode layers 70, and surrounds the charge storage film 32 from the outer circumferential side.

The memory film 30 is provided between the inner circumferential surface of the electrode layer 70 and the outer circumferential surface of the semiconductor body 20 to be continuous in a direction connecting the inner circumferential surface and the outer circumferential surface. The plurality of electrode layers 70 are physically connected to the columnar unit CL via the memory film 30, and are supported by the columnar unit CL.

The outer circumferential surface of the semiconductor body 20 is not exposed to the air gaps 90, and is covered with and protected by the tunneling insulating film 31. The upper surfaces and lower surfaces of the electrode layers 70 also are not exposed to the air gaps 90, and are covered with and protected by a protective film 56. The protective film 56 is the insulating film, e.g., a silicon oxide film.

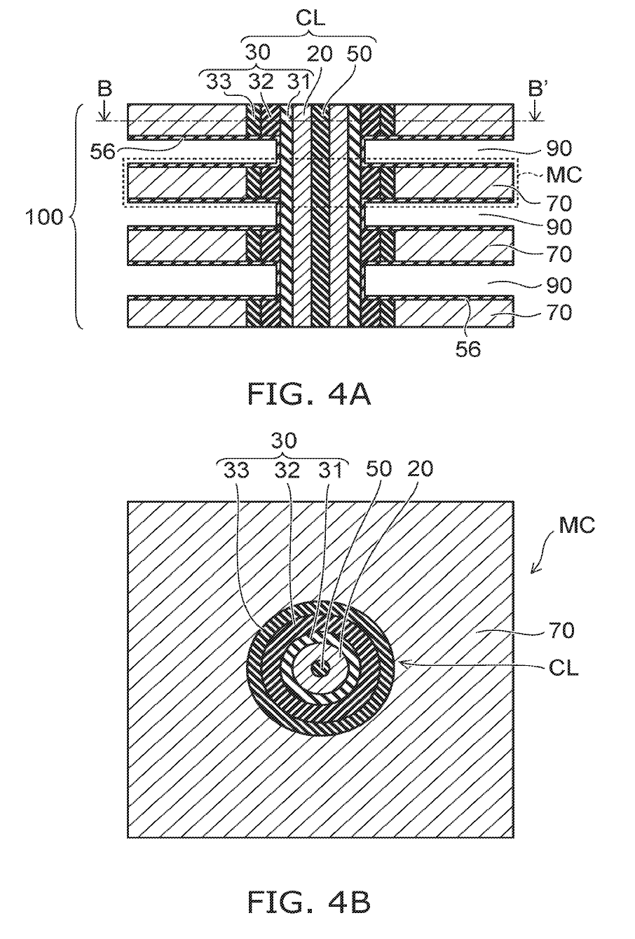

FIG. 4A and FIG. 4B show another example of the columnar unit CL.

FIG. 4A is a cross-sectional view corresponding to FIG. 3A; and FIG. 4B is a B-B′ cross-sectional view of FIG. 4A.

In the example shown in FIG. 4A and FIG. 4B, the semiconductor body 20 is provided in a pipe-like configuration extending in the stacking direction of the stacked body 100; and a core film 50 that is insulative is provided inside the semiconductor body 20.

The semiconductor body 20, the memory film 30, and the electrode layers 70 are included in memory cells MC. One memory cell MC is schematically illustrated by broken lines in FIG. 3A and FIG. 4A. The memory cell MC has a vertical transistor structure in which the electrode layer 70 surrounds the periphery of the semiconductor body 20 with the memory film 30 interposed.

In the memory cell MC having the vertical transistor structure, the semiconductor body 20 functions as a channel; and the electrode layer 70 functions as a control gate. The charge storage film 32 functions as a data storage layer that stores charge injected from the semiconductor body 20.

The semiconductor memory device of the embodiment is a nonvolatile semiconductor memory device that can freely and electrically erase/program data and can retain the memory content even when the power supply is OFF.

The memory cell MC is, for example, a charge trap memory cell. The charge storage film 32 is an insulative film having many trap sites that trap charge and includes, for example, a silicon nitride film. Or, the charge storage film 32 may be a floating gate that is conductive.

The tunneling insulating film 31 is used as a potential barrier when the charge is injected from the semiconductor body 20 into the charge storage film 32 or when the charge stored in the charge storage film 32 is released into the semiconductor body 20. The tunneling insulating film 31 includes, for example, a silicon oxide film.

The blocking insulating film 33 prevents the charge stored in the charge storage film 32 from being released into the electrode layers 70. Also, the blocking insulating film 33 suppresses back-tunneling of electrons from the electrode layers 70 in the erasing operation. The blocking insulating film 33 includes, for example, at least one of a silicon oxide film and a metal oxide film.

The electrode layers 70 also include electrode layers 70 that function as select gates of select transistors. For example, the electrode layer 70 of the uppermost layer functions as a drain-side select gate; and the electrode layer 70 of the lowermost layer functions as a source-side select gate.

The plurality of memory cells MC are provided between the drain-side select transistor having the drain-side select gate as a control gate, and the source-side select transistor having the source-side select gate as a control gate.

The memory cells MC, the drain-side select transistor, and the source-side select transistor are included in one memory string connected in series via the semiconductor body 20. For example, the plurality of memory strings have a staggered arrangement corresponding to the arrangement of the columnar units CL shown in FIG. 2B. Accordingly, the plurality of memory cells MC are provided three-dimensionally in the X-direction, the Y-direction, and the Z-direction.

According to the embodiment as shown in FIG. 3A or FIG. 4A, the air gaps 90 are made between the electrode layers 70 which are the control gates of the memory cells MC adjacent to each other in the stacking direction (the Z-direction). Therefore, the interconnect capacitance between the electrode layers 70 above and below can be reduced; and high-speed operations of the memory cells MC are possible. Further, interference between adjacent cells such as threshold fluctuation due to capacitive coupling between the electrode layers 70 above and below can be suppressed.

Also, because the charge storage film 32 is divided in the stacking direction, the charge stored in the charge storage film 32 does not escape in the stacking direction; and the charge retention characteristics of the memory cell MC are superior.

The connection structure between the semiconductor body 20 and the source layer 40 will now be described.

As shown in FIG. 1, the semiconductor body 20 includes a lower portion 20b positioned lower than the stacked body 100. The lower portion 20b of the semiconductor body 20 is positioned lower than the electrode layer 70 of the lowermost layer and positioned higher than the substrate 10. The source layer 40 surrounds the periphery of the lower portion 20b of the semiconductor body 20.

The memory film 30 is divided in the stacking direction at the height in the vicinity of the intermediate conductive film 44 of the source layer 40. Accordingly, a portion of the side surface of the lower portion 20b of the semiconductor body 20 is not covered with the memory film 30. The intermediate conductive film 44 of the source layer 40 is filled at the periphery of the side surface of the lower portion 20b where the memory film 30 is not provided; and the side surface of the lower portion 20b is covered with the intermediate conductive film 44.

The intermediate conductive film 44 contacts the side surface of the lower portion 20b of the semiconductor body 20. Accordingly, the lower portion 20b of the semiconductor body 20 is electrically connected to the entire source layer 40 via the intermediate conductive film 44. The lower portion 20b of the semiconductor body 20 includes a region having an impurity concentration that is higher than the impurity concentration of the portion of the semiconductor body 20 surrounded with the stacked body 100; and the intermediate conductive film 44 contacts the side surface of the region.

For such a structure in which the source layer 40 electrically contacts the side surface of the semiconductor body 20, compared to a structure in which a conductive layer that functions as the source layer electrically contacts the lower surface of the semiconductor body 20, the contact surface area between the semiconductor body 20 and the source layer 40 can be large; and the contact resistances of both can be low. High-speed operations of the memory cell array 1 are possible.

The connection structure between the semiconductor body 20 and the bit line BL will now be described.

The semiconductor body 20 includes an upper end portion 20a that protrudes above the stacked body 100. The upper end portion 20a of the semiconductor body 20 is positioned higher than the electrode layer 70 of the uppermost layer.

The upper end portion 20a of the semiconductor body 20 has an upper surface and side surface that are not covered with the memory film 30. For example, the semiconductor body 20 contains polycrystalline silicon as a major component; and the upper end portion 20a includes a metal silicide portion 21. The metal silicide portion 21 is provided at the upper surface of the upper end portion 20a and at a portion of the side surface continuing through the corner from the upper surface.

The conductor 61 is provided on the upper end portion 20a of the semiconductor body 20 and at the periphery of the upper end portion 20a. The conductor 61 continuously surrounds the entire periphery of the side surface of the upper end portion 20a of the semiconductor body 20. The conductor 61 covers the upper surface and all of the side surface in a circumferential direction of the upper end portion 20a of the semiconductor body 20 not covered with the memory film 30; and the conductor 61 contacts the upper surface and the side surface.

The conductor 61 contacts the upper surface and side surface of the metal silicide portion 21. The contact resistance between the conductor 61 and the semiconductor body 20 at the interface where the metal silicide portion 21 is formed, is lower than the contact resistance between the conductor 61 and the semiconductor body 20 where the conductor 61 and the semiconductor body 20 contact directly.

The upper end portion 20a of the semiconductor body 20 includes a region having an impurity concentration that is higher than the impurity concentration of the portion of the semiconductor body 20 surrounded with the stacked body 100; and the conductor 61 also contacts the side surface of the region. The conductor 61 also contacts the side surface of the portion of the upper end portion 20a of the semiconductor body 20 positioned lower than the metal silicide portion 21. The metal silicide portion 21 may be formed at the entire side surface of the upper end portion 20a not covered with the memory film 30.

The side surface of the conductor 61 is covered with the insulating layer 51 that is on the stacked body 100 and with the insulating layer 52 that is on the insulating layer 51. The insulating layer 51 is provided between the bottom of the conductor 61 and the electrode layer 70 of the uppermost layer.

The connector 62 is provided on the conductor 61. The connector 62 contacts the upper surface of the conductor 61. The side surface of the connector 62 is covered with the insulating layer 53 that is provided on the insulating layer 52.

The conductor 61 and the connector 62 are metal units that have columnar configurations and contain, for example, tungsten as major components.

The bit line BL is provided on the insulating layer 53. The bit line BL is a metal interconnect and contains, for example, tungsten as a major component. The bit line BL contacts the upper surface of the connector 62. Accordingly, the upper end portion 20a of the semiconductor body 20 is electrically connected to the bit line BL via the conductor 61 and the connector 62.

For such a structure in which the conductor 61 for the connection to the bit line BL contacts the upper surface and side surface of the upper end portion 20a of the semiconductor body 20, compared to a structure in which a conductor contacts only the upper surface of the upper end portion 20a of the semiconductor body 20, the contact surface area between the semiconductor body 20 and the conductor 61 can be large; and the contact resistances of both can be low. High-speed operations of the memory cell array 1 are possible.

This structure makes even higher-speed operations of the memory cell array 1 possible when combined with the structure in which the enlargement of the contact surface area on the source side is realized by the source layer 40 contacting the side surface of the lower portion 20b of the semiconductor body 20.

As thinner films and smaller diameters progress for the semiconductor body 20 to increase the arrangement density of the plurality of memory cells MC, the surface area of the upper surface and the surface area of the lower surface of the semiconductor body 20 having the columnar configuration or the pipe-like configuration also becomes small. On the other hand, the surface area of the side surface of the semiconductor body 20 is independent of the thinner films and the smaller diameters of the semiconductor body 20.

As shown in FIG. 2A, the conductor 61 is provided in a substantially circular columnar configuration. The connector 62 is provided in a substantially elliptical columnar configuration having the X-direction as the major axis. The length of the minor axis of the connector 62 is shorter than the diameter of the conductor 61. The conductor 61 and the connector 62 overlap in the stacking direction and are decentered. In a surface parallel to the XY plane shown in FIG. 2A, the center of the conductor 61 and the center of the connector 62 are shifted and do not match. The shift amount in the Y-direction between the center of the conductor 61 and the center of the connector 62 is larger than the shift amount in the X-direction between the center of the conductor 61 and the center of the connector 62.

As shown in FIG. 2B, the plurality of columnar units CL include a column arranged in one straight line in the X-direction. In the example shown in FIG. 2B, two columnar units CL per one block 100a are arranged in one straight line in the X-direction.

Corresponding to the arrangement of the plurality of columnar units CL, as shown in FIG. 2A, the plurality of conductors 61 include a column arranged in one straight line in the X-direction. In the example shown in FIG. 2A, two conductors 61 per one block 100a are arranged in one straight line in the X-direction. On the other hand, while the plurality of connectors 62 include a column arranged in one straight line in the X-direction across the plurality of blocks 100a, in the example shown in FIG. 2A, the two connectors 62 inside one block 100a are not arranged in one straight line in the X-direction but are arranged at positions shifted from each other in the Y-direction.

Two bit lines BL extend in the X-direction on one column of the plurality of conductors 61 arranged in one straight line in the X-direction. For example, one of the two bit lines BL extending on the plurality of conductors 61 arranged in one straight line in the X-direction in the lowermost column in the plan view of FIG. 2A is a first bit line BL1; and the other is a second bit line BL2. The first bit line BL1 and the second bit line BL2 are adjacent in the Y-direction.

The plurality of connectors 62 include a first connector provided on a first conductor that is one of the two conductors 61 adjacent to each other in the X-direction, and a second connector provided on a second conductor that is the other of the two conductors 61 adjacent to each other in the X-direction.

For example, in the block 100a on the left side of FIG. 2A, one of the two conductors 61 adjacent to each other in the X-direction and arranged under the first bit line BL1 and the second bit line BL2 is a first conductor 61a; and the other is a second conductor 61b. Also, the connector 62 that is provided on the first conductor 61a is a first connector 62a; and the connector 62 that is provided on the second conductor 61b is a second connector 62b.

The first connector 62a and the first conductor 61a overlap in the stacking direction. The first connector 62a is decentered with respect to the first conductor 61a in one direction of the +Y direction or the −Y direction. The second connector 62b and the second conductor 61b overlap in the stacking direction. The second connector 62b is decentered in the other direction of the +Y direction or the −Y direction.

The first bit line BL1 extends in the X-direction right over the first connector 62a and contacts the first connector 62a. The second bit line BL2 extends in the X-direction right over the second connector 62b and is connected to the second connector 62b.

According to the configuration of FIG. 2A, one memory string inside each block 100a is connected to one bit line BL while the bit lines BL are arranged at high density to match the high-density arrangement of the columnar units CL and the conductors 61. Although the connector 62 contacts only the upper surface of the conductor 61 for such a connection, it is difficult for the contact resistance to be problematic because both the conductor 61 and the connector 62 can contain a metal. The contact resistance of the connection structure between the columnar unit CL and the bit line BL can be low by setting the contact surface area of the conductor 61 with the semiconductor body 20 of the columnar unit CL to be sufficiently large.

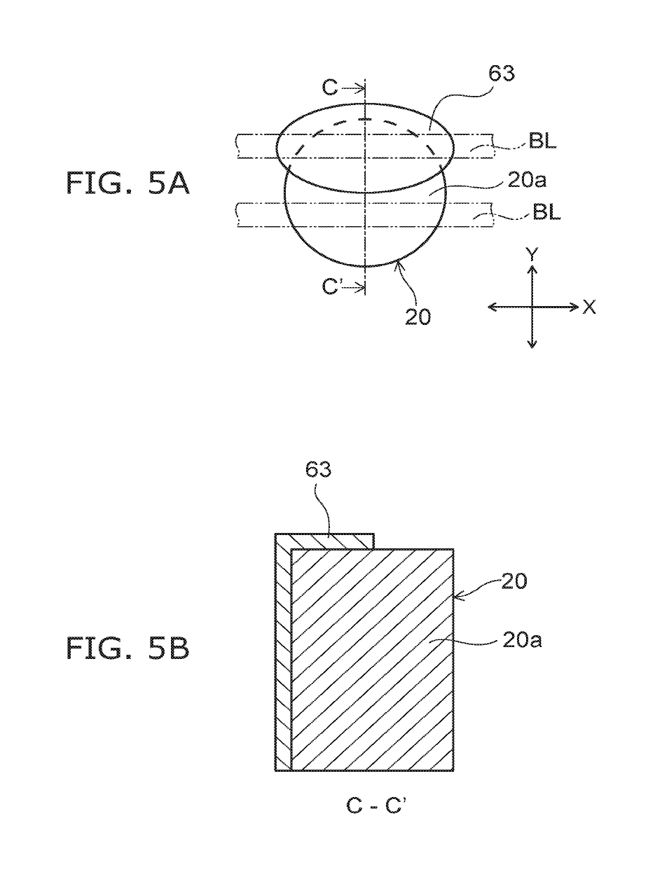

The conductor 61 that contacts the upper end portion 20a of the semiconductor body 20 may be connected directly to the bit line BL without the connector 62 being interposed. Such a configuration example is illustrated in FIG. 5A and FIG. 5B.

FIG. 5A is a schematic top view of the upper end portion 20a of the semiconductor body 20 and a conductor 63; and FIG. 5B is a C-C′ cross-sectional view of FIG. 5A. Also, the bit lines BL are illustrated by superimposed double dot-dash lines in FIG. 5A.

As shown in FIG. 5B, the conductor 63 is provided in a film-like configuration of a metal that covers a portion of the upper surface and a portion in a circumferential direction of the side surface of the upper end portion 20a of the semiconductor body 20. The conductor 63 contains, for example, tungsten as a major component.

As shown in FIG. 5A, the exterior form of the upper surface of the upper end portion 20a of the semiconductor body 20 is formed in a substantially circular configuration. The exterior form of the upper surface of the conductor 63 is formed in a substantially elliptical configuration having the X-direction as the major axis. The center of the conductor 63 is shifted in the Y-direction from the center of the upper end portion 20a of the semiconductor body 20 in the surface parallel to the XY plane shown in FIG. 5A.

As shown in FIG. 5B, the conductor 63 contacts a portion of the upper surface and a portion of the side surface of the upper end portion 20a of the semiconductor body 20. The contact portion of the upper end portion 20a of the semiconductor body 20 with the conductor 63 may be metal-silicided.

As shown in FIG. 5A, for example, two bit lines BL extend in the X-direction over one columnar unit CL, i.e., one semiconductor body 20; and one bit line BL of the two bit lines BL extends in the X-direction right over the conductor 63 and contacts the upper surface of the conductor 63. Accordingly, the upper end portion 20a of the semiconductor body 20 is electrically connected to the bit line BL via the conductor 63.

Because the conductor 63 contacts not only the upper surface of the upper end portion 20a of the semiconductor body 20 but also the side surface of the upper end portion 20a, the contact surface area between the conductor 63 and the semiconductor body 20 can be set to be large independently of thinner films and smaller diameters for the semiconductor body 20. This reduces the electrical contact resistance between the semiconductor body 20 and the bit line BL, and makes high-speed operations of the memory cell array possible.

Also, the conductor 63 and the entire surface of the upper surface of the upper end portion 20a of the semiconductor body 20 do not overlap. As shown in FIG. 5A, it is possible to connect one bit line BL to one memory string inside each block 100a while arranging the bit lines BL at high density by decentering the conductor 63 in the Y-direction from the center of the upper surface of the upper end portion 20a.

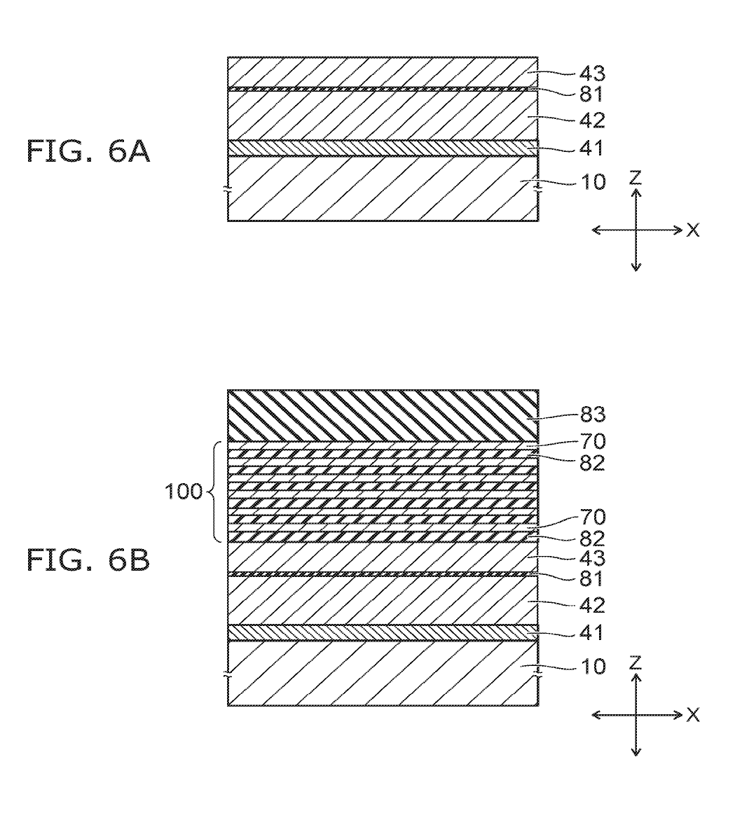

A method for manufacturing the semiconductor device of the embodiment will now be described with reference to FIG. 6A to FIG. 17B.

As shown in FIG. 6A, the first conductive layer 41 is formed on the substrate 10; the second conductive layer 42 is formed on the first conductive layer 41; a sacrificial layer 81 is formed on the second conductive layer 42; and the third conductive layer 43 is formed on the sacrificial layer 81.

The first conductive layer 41 is, for example, a metal layer. The second conductive layer 42 and the third conductive layer 43 are, for example, silicon layers. The sacrificial layer 81 is a layer of a material different from the second conductive layer 42 and the third conductive layer 43 and is, for example, a silicon nitride layer.

As shown in FIG. 6B, the stacked body 100 is formed on the third conductive layer 43. The stacked body 100 includes the electrode layers 70 as first layers, and sacrificial layers (or insulating layers) 82 as second layers. The forming the sacrificial layer 82 and the forming the electrode layer 70 are repeated alternately.

The electrode layer 70 is, for example, a metal layer. The metal layer contains, for example, mainly tungsten or molybdenum. The sacrificial layer 82 is, for example, a silicon oxide layer. Or, the sacrificial layer 82 is a different type of metal layer from the electrode layer 70. For example, the electrode layer 70 is a tungsten layer; and the sacrificial layer 82 is a molybdenum layer.

A third layer 83 is formed on the stacked body 100. The third layer 83 is a sacrificial layer that is removed in a subsequent process, or an insulating layer that remains as one element of the device. The third layer 83 is, for example, a silicon oxide layer.

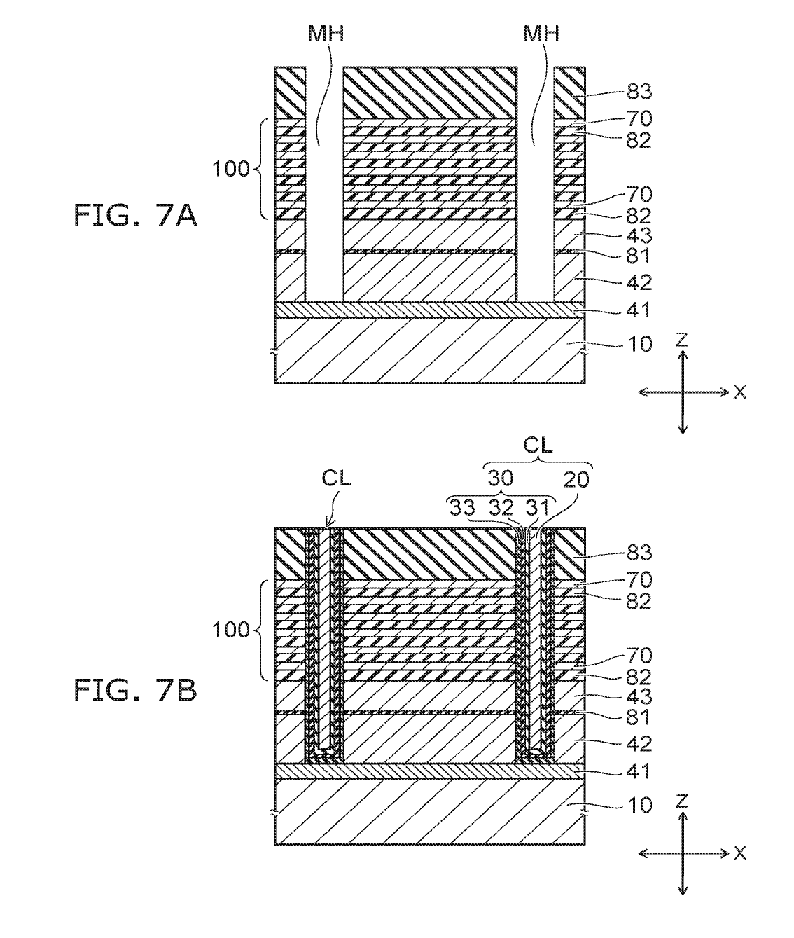

As shown in FIG. 7A, a memory hole MH is made in the third layer 83, the stacked body 100, and the layers under the stacked body 100. For example, a plurality of memory holes MH are made by reactive ion etching (RIE) using a not-shown mask.

The memory hole MH pierces the third layer 83, the stacked body 100, the third conductive layer 43, the sacrificial layer 81, and the second conductive layer 42, extends in the stacking direction (the Z-direction), and reaches the first conductive layer 41.

As shown in FIG. 7B, each of the films included in the columnar unit CL is formed inside the memory hole MH by chemical vapor deposition (CVD) or atomic layer deposition (ALD). First, the blocking insulating film 33 is formed conformally on the side surface and bottom of the memory hole MH. The charge storage film 32 is formed on the inner side of the blocking insulating film 33; the tunneling insulating film 31 is formed on the inner side of the charge storage film 32; and the semiconductor body 20 is formed on the inner side of the tunneling insulating film 31.

Each of the films of the columnar unit CL is deposited also on the upper surface of the third layer 83. The upper surface of the columnar unit CL and the upper surface of the third layer 83 are planarized by removing the films by, for example, chemical mechanical polishing (CMP). The upper surface of the semiconductor body 20 is exposed. For example, an impurity such as phosphorus, arsenic, boron, aluminum, or the like is doped into the exposed upper surface of the semiconductor body 20. The impurity that is doped is diffused into the upper end portion of the semiconductor body 20 by heat treatment.

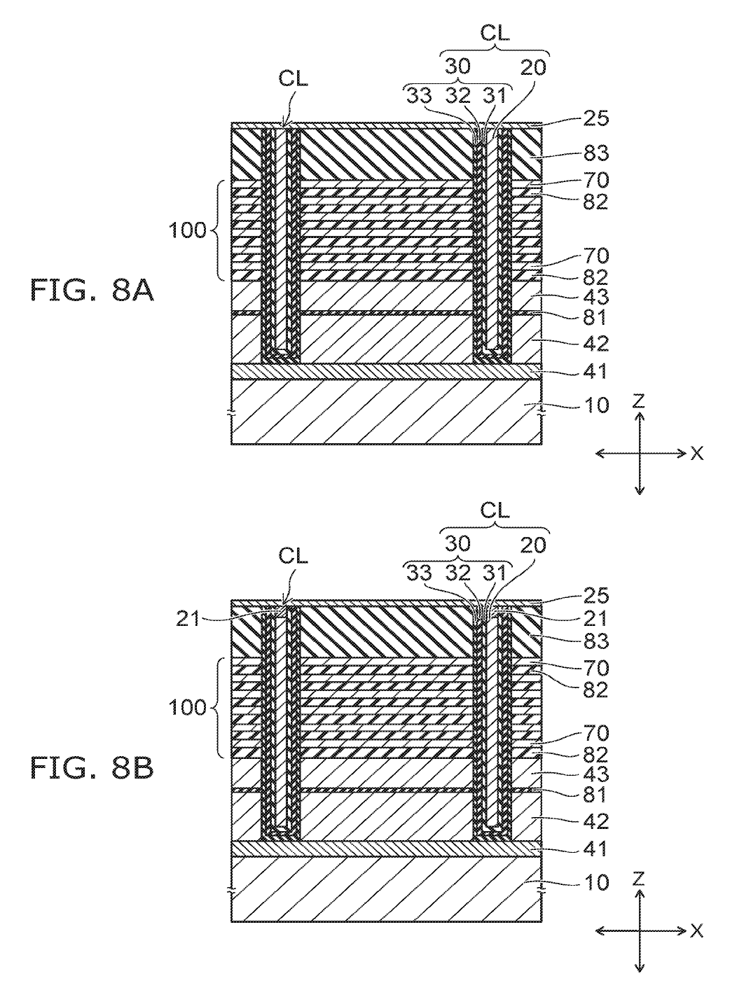

Then, as shown in FIG. 8A, a metal film 25 is formed on the upper surface of the third layer 83 to cover the upper surface of the columnar unit CL. For example, the metal film 25 is formed by sputtering. The metal film 25 contacts the upper surface of the semiconductor body 20 containing silicon.

Then, the metal contained in the metal film 25 and the silicon contained in the semiconductor body 20 are caused to react by heat treatment. Metal-siliciding progresses from the upper surface of the semiconductor body 20 contacting the metal film 25; and the metal silicide portion 21 is formed in the upper end portion of the semiconductor body 20 including the upper surface of the semiconductor body 20 and the side surface at the vicinity of the upper surface of the semiconductor body 20 as shown in FIG. 8B.

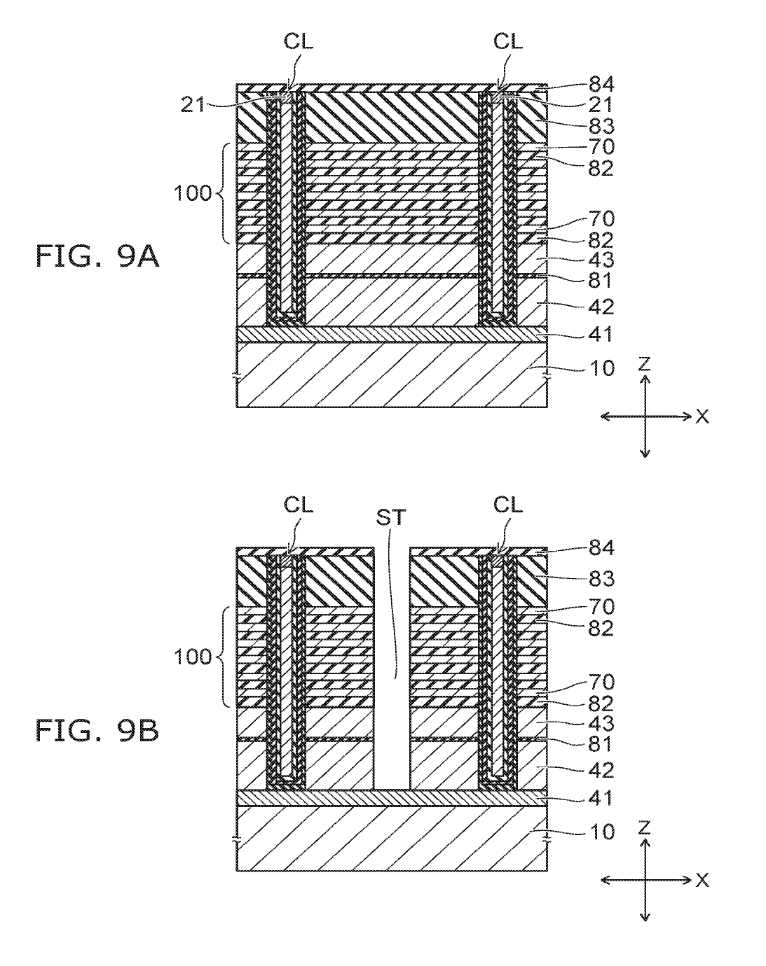

Subsequently, after removing the unreacted metal film 25, a cover film 84 is formed on the upper surface of the third layer 83 as shown in FIG. 9A. The cover film 84 covers the upper surface of the columnar unit CL. The cover film 84 is, for example, a silicon oxide film.

As shown in FIG. 9B, slit ST is made in the cover film 84, the third layer 83, the stacked body 100, and the layers under the stacked body 100. For example, a plurality of slits ST are made by RIE using a not-shown mask.

The slit ST pierces the cover film 84, the third layer 83, the stacked body 100, the third conductive layer 43, the sacrificial layer 81, and the second conductive layer 42, extends in the stacking direction (the Z-direction), and reaches the first conductive layer 41. Also, the slit ST extends into the page surface (the Y-direction) and divides the stacked body 100 into a plurality of blocks in the X-direction.

Then, the sacrificial layer 81 is removed using an etchant or an etching gas supplied to the slit ST. For example, the sacrificial layer 81 which is a silicon nitride layer is etched by supplying an etchant containing phosphoric acid to the slit ST.

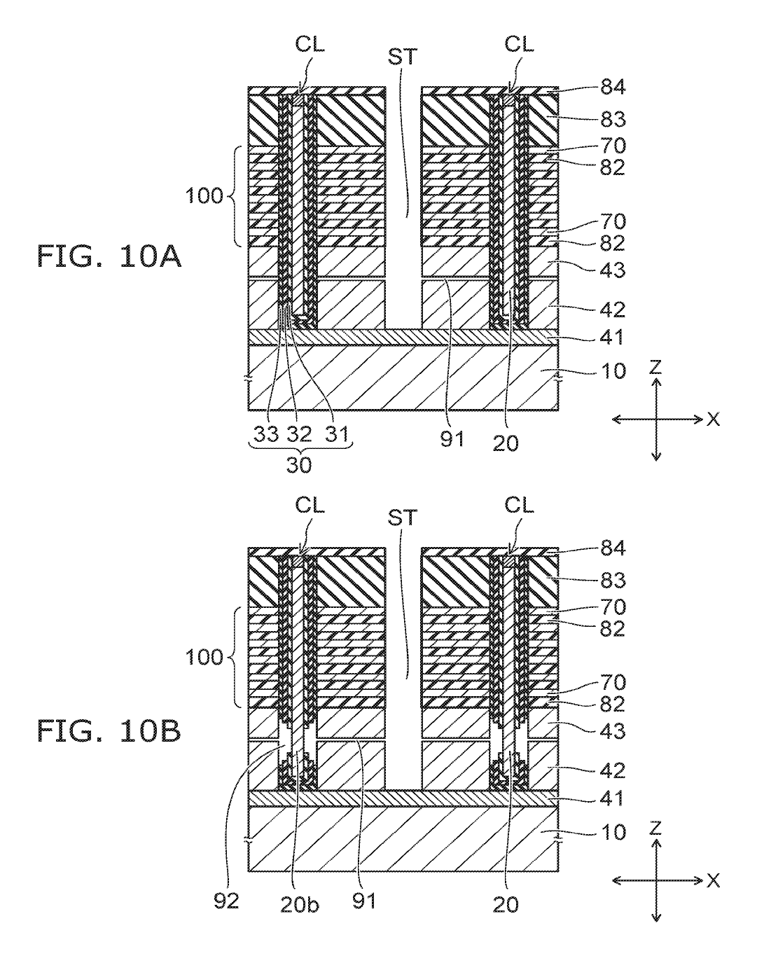

The sacrificial layer 81 is removed; and an air gap 91 is made between the third conductive layer 43 and the second conductive layer 42 as shown in FIG. 10A.

Then, a portion of the memory film 30 is removed through the air gap 91. The etchant or the etching gas supplied to the slit ST enters the air gap 91. Then, etching of the memory film 30 progresses from the outermost circumferential surface of the memory film 30 exposed in the air gap 91.

A portion of the memory film 30 in the vicinity of the air gap 91 is removed; and an air gap 92 is made at the periphery of the lower portion 20b of the semiconductor body 20 as shown in FIG. 10B. The side surface of the lower portion 20b of the semiconductor body 20 is exposed in the air gap 92. The air gap 92 communicates with the slit ST through the air gap 91.

Because the upper surface of the memory film 30 is covered with the cover film 84, the etching does not progress from the upper surface of the memory film 30. For example, in the case where the cover film 84 is a silicon oxide film and is the same material as a film (e.g., the tunneling insulating film 31) included in the memory film 30, the cover film 84 also is etched when etching the memory film 30. But the disappearance of the cover film 84 can be prevented by forming the film thickness of the cover film 84 to be thicker than the film thickness of the film to be etched (e.g., the tunneling insulating film 31).

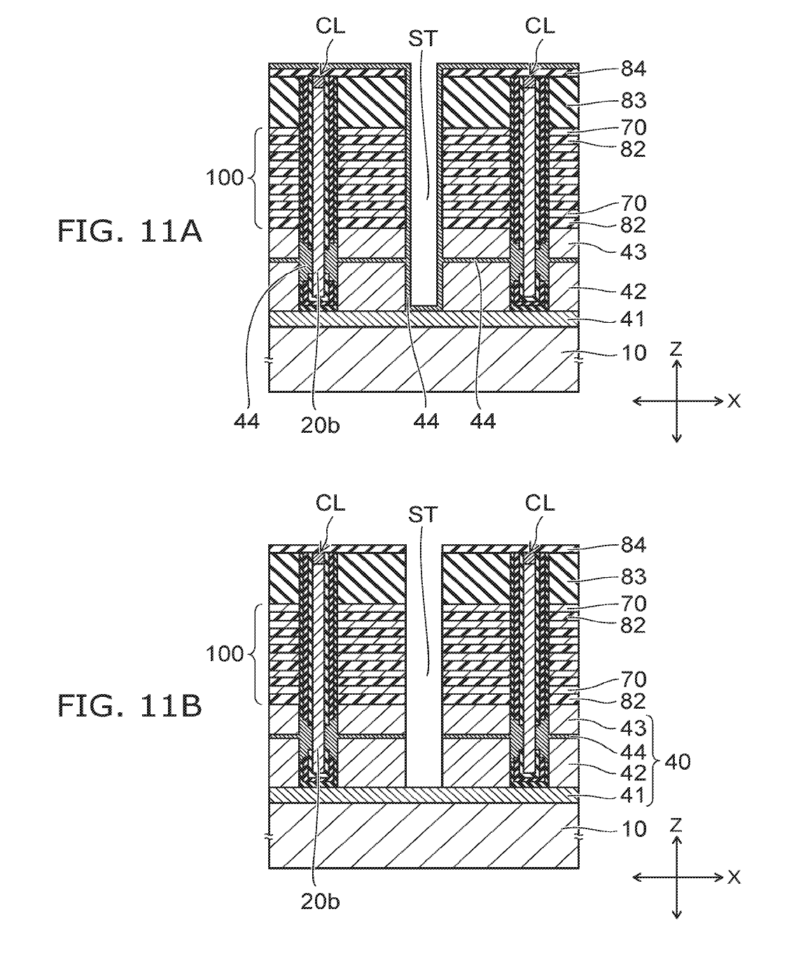

Then, as shown in FIG. 11A, the intermediate conductive film 44 is formed in the air gap 91 and the air gap 92. The intermediate conductive film 44 is, for example, a silicon film formed by CVD or ALD. The source gas enters the air gap 91 and the air gap 92 through the slit ST.

The second conductive layer 42 and the third conductive layer 43 which are both silicon layers are doped with an impurity. The intermediate conductive film 44 also is doped with the impurity by a heat treatment when forming the intermediate conductive film 44 or in a subsequent heat treatment. Or, the intermediate conductive film 44 is doped with the impurity by forming the intermediate conductive film 44 using a film formation gas containing the impurity. The lower portion 20b of the semiconductor body 20 that contacts the intermediate conductive film 44 is doped with the impurity by a heat treatment when forming the intermediate conductive film 44 or in a subsequent heat treatment.

As shown in FIG. 11A, the intermediate conductive film 44 is formed also on the upper surface of the cover film 84 and the side surface and bottom of the slit ST; and this portion of the intermediate conductive film 44 is removed as shown in FIG. 11B.

Subsequently, the cover film 84, the third layer 83, and the sacrificial layer 82 are removed. These are formed of the same material and are removed collectively using the same etchant or etching gas. For example, the cover film 84, the third layer 83, and the sacrificial layer 82 which are silicon oxide films are removed using an etchant containing hydrofluoric acid. The sacrificial layer 82 is etched by an etchant supplied to the slit ST.

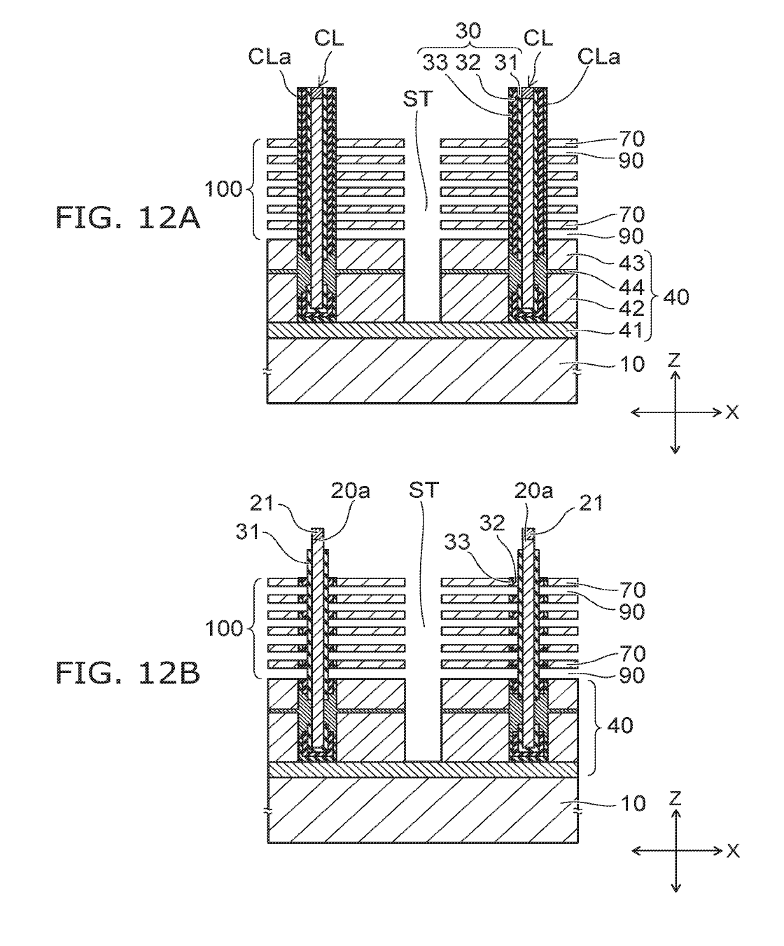

The cover film 84 and the third layer 83 are removed; and the upper end portion CLa of the columnar unit CL that protrudes above the stacked body 100 is exposed as shown in FIG. 12A.

The sacrificial layer 82 is removed; and the air gaps 90 are made between the electrode layers 70, and between the third conductive layer 43 of the source layer 40 and the electrode layer 70 of the lowermost layer.

Then, etching of a portion of the memory film 30 exposed in the air gaps 90 progresses by using an etchant or an etching gas supplied through the slits ST and the air gaps 90. The portions of the blocking insulating film 33 and the charge storage film 32 adjacent to the air gaps 90 are removed; and the blocking insulating film 33 and the charge storage film 32 are divided in the stacking direction (the Z-direction) as shown in FIG. 12B.

Also, in this etching, the blocking insulating film 33 and the charge storage film 32 of the upper end portion CLa of the columnar unit CL also are etched. At the upper end portion CLa, while the side surface of the tunneling insulating film 31 is covered with the charge storage film 32 and the blocking insulating film 33, the upper surface of the tunneling insulating film 31 is exposed. Etching of the tunneling insulating film 31 also progresses from the exposed upper surface in the etching of the blocking insulating film 33 and the charge storage film 32 although at a lower rate than these films.

Therefore, the one portion of the tunneling insulating film 31 of the upper end portion CLa formed on the side surface in the vicinity of the upper surface of the semiconductor body 20 also is removed; and the upper surface and side surface of the upper end portion 20a of the semiconductor body 20 are exposed as shown in FIG. 12B. The upper surface and side surface of the metal silicide portion 21 that are formed at the upper end portion 20a of the semiconductor body 20 are exposed.

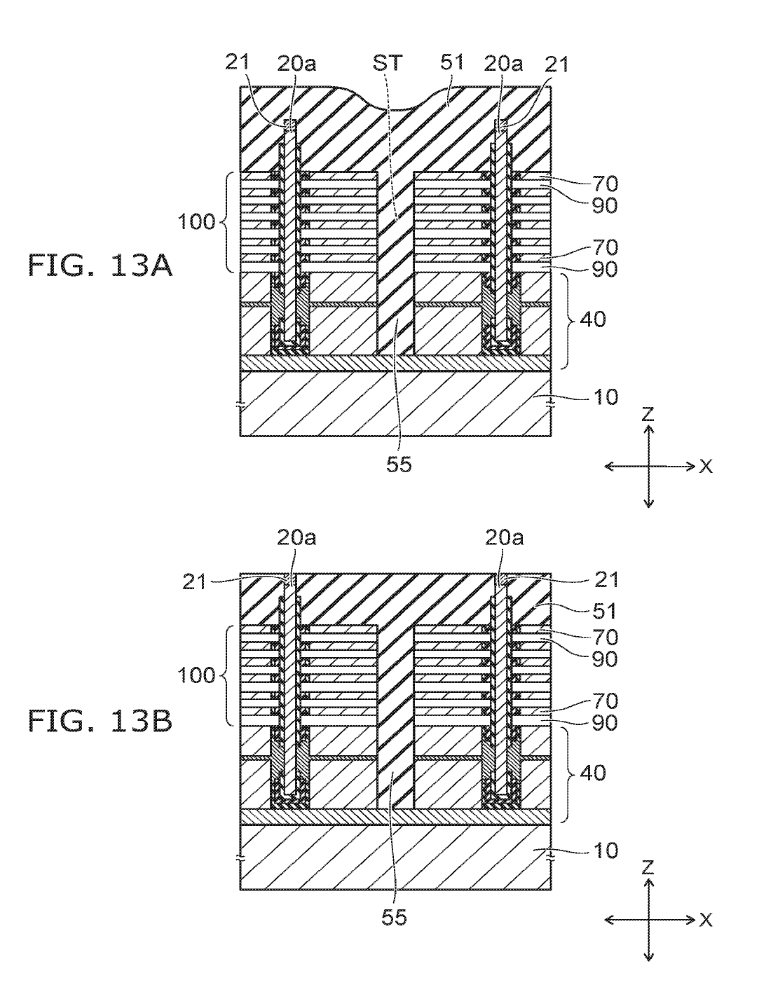

Then, as shown in FIG. 13A, the insulating layer 51 is formed on the stacked body 100 to cover the upper end portion 20a of the semiconductor body 20. A portion of the insulating layer 51 is filled into the slits ST to become the insulating separation units 55. Also, the coverage of the insulating layer 51 is poor; and the insulating layer 51 is not filled into the air gaps 90 between the electrode layers 70.

Then, for example, the upper surface of the insulating layer 51 is planarized as shown in FIG. 13B by CMP. The upper surface of the upper end portion 20a of the semiconductor body 20, i.e., the upper surface of the metal silicide portion 21 in the example, is exposed from the insulating layer 51. The metal silicide portion 21 is used as a stopper in the CMP. By using the metal silicide as the stopper, compared to using silicon as the stopper, the completion timing of the CMP can be controlled with high precision; and the planarizing precision can be increased. The increase of the planarizing precision of the upper surface of the insulating layer 51 makes the process of forming the interconnects and the via holes in subsequent processes easy.

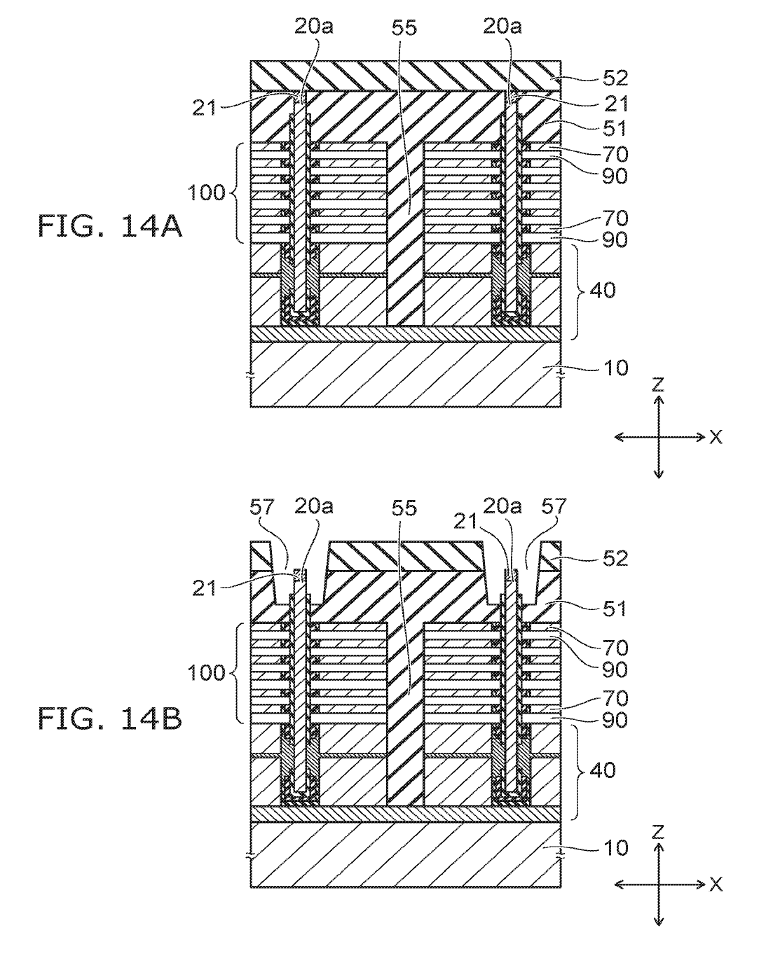

Then, the insulating layer 52 is formed on the insulating layer 51 as shown in FIG. 14A. The insulating layer 52 covers the upper surface of the upper end portion 20a of the semiconductor body 20.

Then, via holes 57 are made in the insulating layer 52 and the insulating layer 51 as shown in FIG. 14B. The bottoms of the via holes 57 do not reach the electrode layer 70 of the uppermost layer. The upper surface and side surface of the upper end portion 20a of the semiconductor body 20 including the metal silicide portion 21 are exposed inside the via holes 57.

The conductor 61 shown in FIG. 1 is formed by filling a metal material into the via hole 57. The conductor 61 contacts the upper surface and side surface of the upper end portion 20a of the semiconductor body 20.

Subsequently, as shown in FIG. 1, the insulating layer 53 is formed on the insulating layer 52. A not-shown via hole that reaches the upper surface of the conductor 61 is made in the insulating layer 53; and the connector 62 is formed by filling a metal material into the via hole. The bottom of the connector 62 contacts the conductor 61. Subsequently, the bit line BL that contacts the connector 62 is formed on the insulating layer 53.

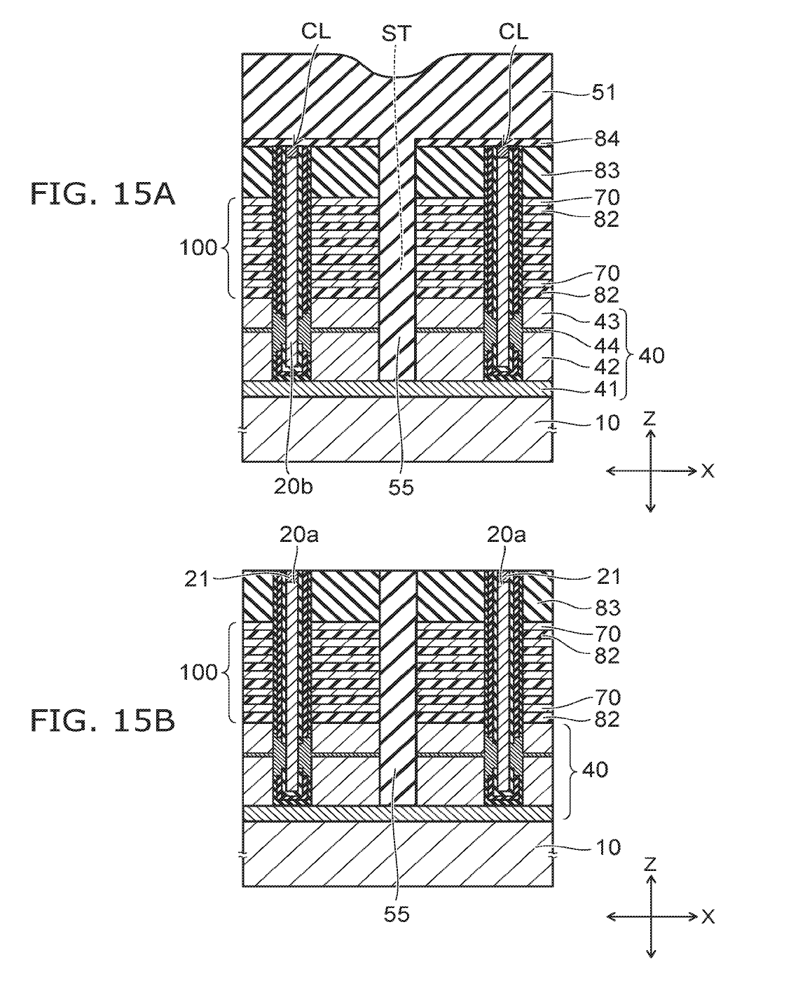

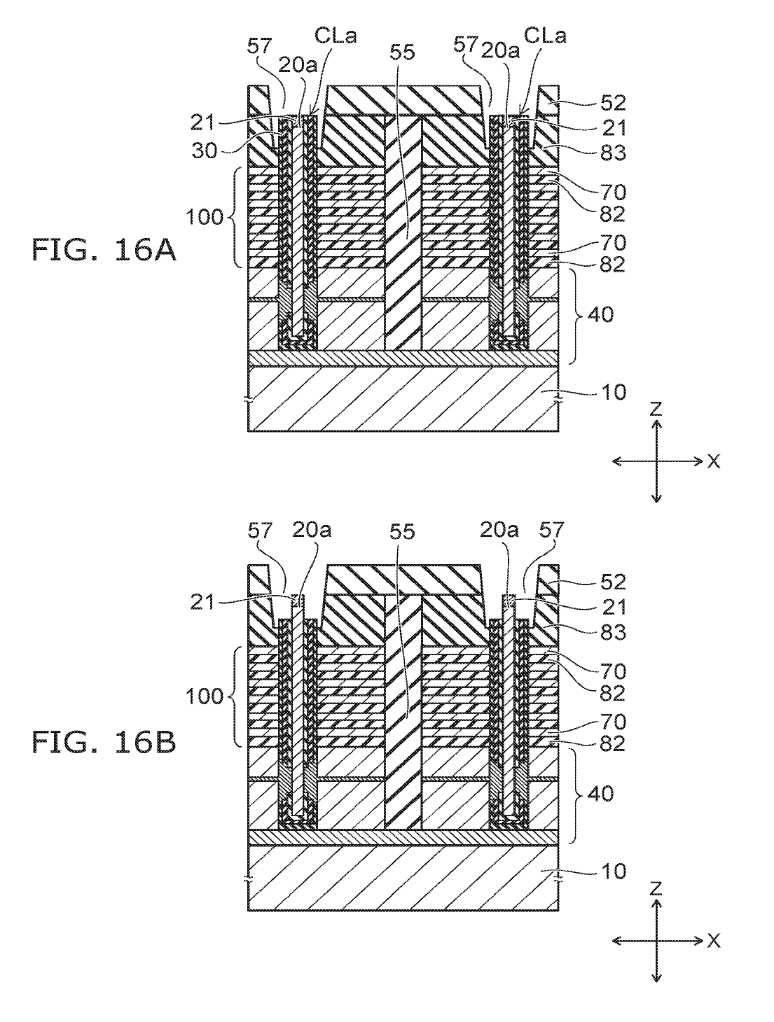

FIG. 15A to FIG. 16B are schematic cross-sectional views showing another example of a method for manufacturing the semiconductor device of the embodiment.

After the process of FIG. 11B, the insulating layer 51 is formed on the cover film 84 as shown in FIG. 15A. A portion of the insulating layer 51 is filled into the slit ST and is used to form the insulating separation unit 55.

Subsequently, the insulating layer 51 and the cover film 84 are planarized by CMP; and the upper surface of the semiconductor body 20 is exposed as shown in FIG. 15B. The metal silicide portion 21 is used as a stopper in the CMP.

Subsequently, as shown in FIG. 16A, the insulating layer 52 is formed on the third layer 83 to cover the columnar unit CL and the insulating separation unit 55; further, the via hole 57 is made in the insulating layer 52 and the third layer 83; and the upper surface and side surface of the upper end portion CLa of the columnar unit CL are exposed inside the via hole 57.

Then, the memory film 30 of the upper end portion CLa is removed by etching; and the upper surface and side surface of the upper end portion 20a of the semiconductor body 20 are exposed inside the via hole 57 as shown in FIG. 16B.

Subsequently, the conductor 61 shown in FIG. 1 is formed by filling a metal material into the via hole 57.

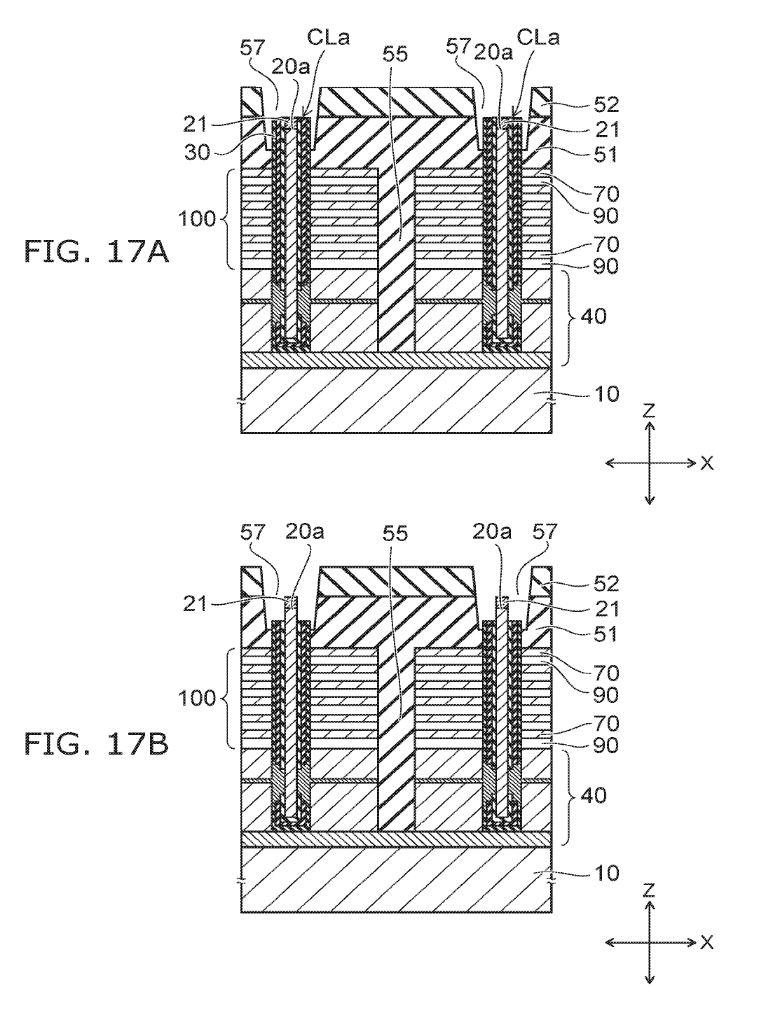

FIG. 17A and FIG. 17B are schematic cross-sectional views showing yet another example of a method for manufacturing the semiconductor device of the embodiment.

After the process of FIG. 12A, the insulating layer 51 is formed on the stacked body 100 as shown in FIG. 17A without etching the memory film 30. A portion of the insulating layer 51 is filled into the slit ST and is used to form the insulating separation unit 55. Also, the coverage of the insulating layer 51 is poor; and the insulating layer 51 is not filled into the air gaps 90 between the electrode layers 70.

The insulating layer 52 is formed on the insulating layer 51; further, the via hole 57 is made in the insulating layer 52 and the insulating layer 51; and the upper surface and side surface of the upper end portion CLa of the columnar unit CL are exposed inside the via hole 57.

Then, the memory film 30 of the upper end portion CLa is removed by etching; and the upper surface and side surface of the upper end portion 20a of the semiconductor body 20 are exposed inside the via hole 57 as shown in FIG. 17B. Subsequently, the conductor 61 shown in FIG. 1 is formed by filling a metal material into the via hole 57.

Also, if the cover film 84 and the third layer 83 are of a material that is different from the second layer 82 in FIG. 11B, the second layer 82 can be removed in the next process to make the air gaps 90 between the electrode layers 70 in a state in which the cover film 84 and the third layer 83 remain. Etching of a portion of the memory film 30 exposed in the air gaps 90 progresses in the state in which the memory film 30 of the upper end portion CLa of the columnar unit CL is covered with the cover film 84 and the third layer 83; and subsequently, processes similar to those of FIG. 15A to FIG. 16B are continued.

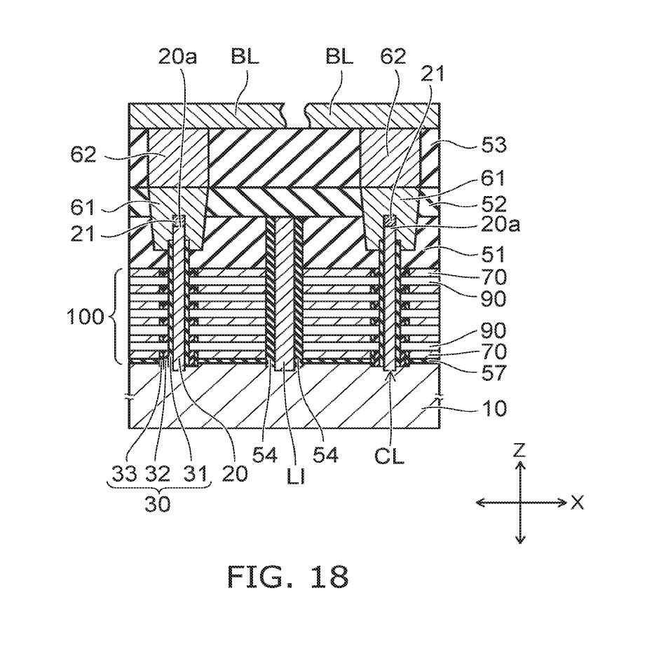

FIG. 18 is a schematic cross-sectional view of a memory cell array of another embodiment.

In FIG. 18, the same components as the components shown in FIG. 1 are marked with the same reference numerals, and a detailed description thereof is omitted.

The stacked body 100 including the electrode layers 70 is provided on the substrate 10 with the insulating film 57 interposed. The insulating film 57 is provided between the electrode layer 70 of the lowermost layer and the surface (the major surface) of the substrate 10.

An interconnect portion LI pierces the stacked body 100 and extends in the stacking direction (the Z-direction). The interconnect portion LI is arranged in a layout similar to that of the insulating separation unit 55 shown in FIG. 2A and FIG. 2B and spreads in a plate configuration in the Z-direction and the Y-direction (the page surface depth direction in FIG. 18). The interconnect portion LI divides the stacked body 100 into a plurality of blocks in the X-direction.

An insulating film 54 is provided on the side surface of the interconnect portion LI. The insulating film 54 is provided between the stacked body 100 and the interconnect portion LI.

The interconnect portion LI is, for example, a metal film containing tungsten as a major component. The lower end of the interconnect portion LI contacts the substrate 10. The upper end of the interconnect portion LI is connected to a not-shown source line provided to be higher than the stacked body 100.

The lower end of the semiconductor body 20 contacts the substrate 10. For example, the substrate 10 is a silicon substrate doped with an impurity. Accordingly, the lower end of the semiconductor body 20 is electrically connectable to the source line via the substrate 10 and the interconnect portion LI.

By controlling the potential applied to the electrode layer 70 of the lowermost layer provided, with the insulating film 57 interposed, on the surface of the substrate 10, a channel is induced in the surface of the substrate 10 between the lower end of the interconnect portion LI and the lower end of the semiconductor body 20; and a current can be caused to flow between the lower end of the interconnect portion LI and the lower end of the semiconductor body 20.

The electrode layer 70 of the lowermost layer functions as a control gate for inducing the channel in the surface of the substrate 10; and the insulating film 57 functions as a gate insulator film. Because the insulating film 57 having a dielectric constant that is higher than that of air is between the surface of the substrate 10 and the electrode layer 70 of the lowermost layer instead of the air gap, high-speed operations are possible due to the capacitive coupling between the electrode layer 70 of the lowermost layer and the surface of the substrate 10.

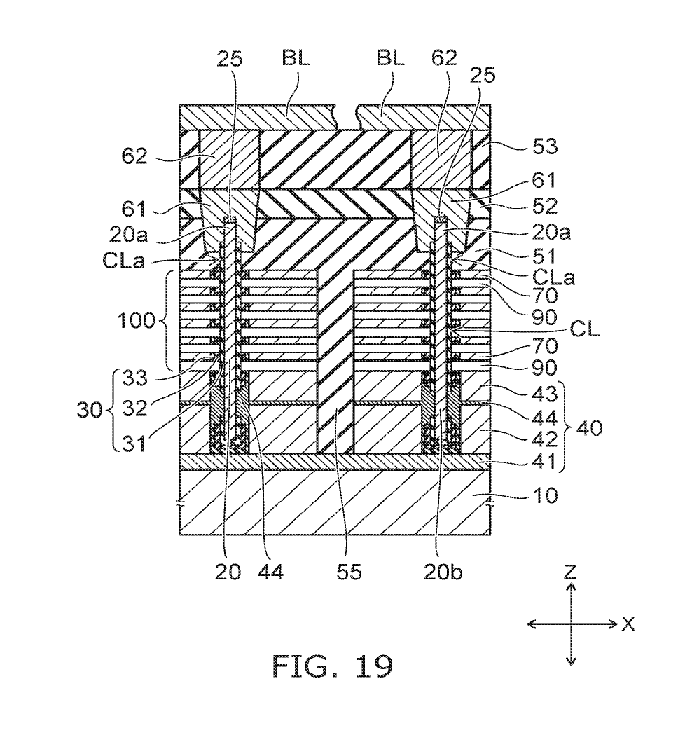

FIG. 19 is a schematic cross-sectional view of a memory cell array of yet another embodiment.

In FIG. 19, the same components as the components shown in FIG. 1 are marked with the same reference numerals, and a detailed description thereof is omitted.

The metal film 25 is provided on the upper surface of the upper end portion 20a of the semiconductor body 20. In the process shown in FIG. 8A described above, the metal film 25 that is formed on the upper surface of the third layer 83 is patterned to cover the upper surface of the columnar unit CL. The metal film 25 remains only on the upper surface of the semiconductor body 20. Or, the metal film 25 is formed selectively on the upper surface of the semiconductor body 20 in a state in which the other regions are covered with a mask.

The metal film 25 that is formed on the upper surface of the semiconductor body 20 also increases the planarizing precision by being used as a stopper in the CMP of the insulating layer 51 shown in FIG. 13B.

Also, the conductor 61 electrically contacts the upper surface and side surface of the upper end portion 20a of the semiconductor body 20 with the metal film 25 which is a conductor similar to the conductor 61.

When forming the stacked body 100 shown in FIG. 6B, a first sacrificial layer may be formed as the first layer instead of the electrode layer 70.

In such a case, after making the slits ST shown in FIG. 9B, air gaps are made between sacrificial layers (the second sacrificial layers) 82 by removing the first sacrificial layers using an etchant or an etching gas supplied through the slits ST. For example, the first sacrificial layers which are silicon nitride layers can be removed using an etchant containing phosphoric acid.

Subsequently, the electrode layers 70 are formed between the sacrificial layers 82 by supplying a source gas to the air gaps between the sacrificial layers 82 through the slits ST by CVD or ALD. Subsequently, processes similar to those of FIG. 10A and subsequent figures are continued.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

1: A semiconductor device, comprising:
a substrate;
a stacked body provided above the substrate, the stacked body including a plurality of electrode layers stacked with an insulator interposed;
a semiconductor body extending in a stacking direction through the stacked body, the semiconductor body including an upper end portion protruding above the stacked body;
a stacked film provided between the semiconductor body and the electrode layers, the stacked film including a charge storage portion;
a conductor provided at an upper surface and an outer side surface of the upper end portion of the semiconductor body in one body, the conductor electrically contacting the upper surface and the outer side surface; and
an interconnect provided above the conductor, the interconnect being electrically connected to the conductor.

2: The semiconductor device according to claim 1, wherein a portion of the upper end portion protruding above the stacked body contain a metal silicide.

3: The semiconductor device according to claim 1, wherein a metal film is formed selectively at the upper surface of the upper end portion of the semiconductor body.

4: The semiconductor device according to claim 1, wherein the upper end portion of the semiconductor body includes a region having a higher impurity concentration than a portion of the semiconductor body surrounded with the stacked body.

5: The semiconductor device according to claim 1, wherein the conductor covers the upper surface and all of the outer side surface in a circumferential direction of the upper end portion of the semiconductor body.

6: The semiconductor device according to claim 1, wherein
the conductor covers a portion of the upper surface of the upper end portion of the semiconductor body, one other portion of the upper surface not being covered with the conductor, and
the conductor covers a portion in a circumferential direction of the side surface of the upper end portion of the semiconductor body, one other portion in the circumferential direction of the side surface not being covered with the conductor.

7: The semiconductor device according to claim 5, further comprising a connector provided between the conductor and the interconnect, and connected to the conductor and the interconnect.

8: The semiconductor device according to claim 7, wherein
the conductor and the connector are provided in columnar configurations, and
the conductor and the connector overlap in the stacking direction and are decentered.

9: The semiconductor device according to claim 8, wherein
a plurality of columnar units, a plurality of the conductors, and a plurality of the connectors are arranged in a first direction intersecting the stacking direction, one columnar unit including the semiconductor body and the stacked film,
two interconnects extend in the first direction above one column of the plurality of conductors arranged in the first direction,
the plurality of connectors include a first connector and a second connector, the first connector being provided on a first conductor, the second connector being provided on a second conductor, the first conductor being one of two conductors adjacent to each other in the first direction, the second conductor being the other of the two conductors adjacent to each other in the first direction, and
the first connector is connected to a first interconnect, and the second connector is connected to a second interconnect, the first interconnect being one of the two interconnects, the second interconnect being the other of the two interconnects.

10: The semiconductor device according to claim 1, further comprising a conductive layer provided between the substrate and the stacked body, the conductive layer contacting a side surface of a lower portion of the semiconductor body positioned lower than the stacked body.

11: The semiconductor device according to claim 1, wherein an air gap is provided as the insulator between the plurality of electrode layers.

12: The semiconductor device according to claim 1, wherein
the stacked film includes:
a first insulating film provided between the semiconductor body and the charge storage portion;
a charge storage film as the charge storage portion; and
a second insulating film provided between the charge storage portion and the electrode layers.

13: The semiconductor device according to claim 12, wherein a first air gap is provided as the insulator between the plurality of electrode layers.

14: The semiconductor device according to claim 13, wherein
a second air gap is provided between the first insulating film and the first air gap, the second air gap being continuous with the first air gap, and
the charge storage film is separated in the stacking direction with the second air gap interposed.

15: The semiconductor device according to claim 1, further comprising an interconnect portion extending in the stacking direction, the interconnect portion dividing the stacked body in a first direction and including a lower end contacting the substrate, the first direction intersecting the stacking direction,
the semiconductor body including a lower end contacting the substrate,
the semiconductor body and the interconnect portion being connectable via the substrate.

16: A method for manufacturing a semiconductor device, comprising:
making a hole piercing a stacked body and a third layer formed on the stacked body, the stacked body including a plurality of first layers and a plurality of second layers, the first layers and the second layers including a first layer and a second layer stacked alternately;
forming a columnar unit inside the hole, the columnar unit including a stacked film including a charge storage film, and a semiconductor body, the stacked film being formed at a side surface of the hole, the semiconductor body being formed at a side surface of the stacked film;
exposing an upper end portion of the columnar unit to protrude above the stacked body;
exposing an upper surface and a side surface of an upper end portion of the semiconductor body by removing the stacked film of the exposed upper end portion of the columnar unit;
forming a conductor at the exposed upper surface and side surface of the semiconductor body; and
forming an interconnect above the conductor, the interconnect being electrically connected to the conductor.

17: The method for manufacturing the semiconductor device according to claim 16, further comprising doping an impurity into the upper end portion of the semiconductor body.

18: The method for manufacturing the semiconductor device according to claim 16, wherein
the semiconductor body contains silicon, and
the method further comprises forming a metal silicide portion in the upper end portion of the semiconductor body by causing the silicon of the upper end portion of the semiconductor body to react with a metal.

19: The method for manufacturing the semiconductor device according to claim 16, further comprising:
making a slit piercing the stacked body; and
making an air gap between the plurality of first layers by removing the plurality of second layers by etching through the slit.

20: The method for manufacturing the semiconductor device according to claim 19, wherein the charge storage film is divided in a stacking direction by removing a portion of the charge storage film by etching through the slit and the air gap when removing the stacked film of the upper end portion of the columnar unit.
